(19) United States
(12) Patent Application Publication
(10) Pub. No.: US 2024/0292529 A1
(43) Pub. Date: Aug. 29, 2024

(54) CIRCUIT BOARD AND METHOD OF FABRICATING CIRCUIT BOARD

(71) Applicant: SAMSUNG ELECTRO-MECHANICS CO., LTD., Suwon-si (KR)

(72) Inventors: Inhwan Oh, Suwon-si (KR); Sanghoon Kim, Suwon-si (KR); Chulmin Lee, Suwon-si (KR); Chanhoon Ko, Suwon-si (KR); Kyounghee Lim, Suwon-si (KR); Sohyun Bae, Suwon-si (KR)

(73) Assignee: SAMSUNG ELECTRO-MECHANICS CO., LTD., Suwon-si (KR)

(21) Appl. No.: 18/399,156

(22) Filed: Dec. 28, 2023

(30) Foreign Application Priority Data
Feb. 27, 2023 (KR) 10-2023-0026119

(51) Int. Cl. H05K 1/02; H05K 1/11; H05K 3/06

(52) U.S. Cl. CPC H05K 1/0298; H05K 1/111; H05K 3/06; H05K 2201/10378; H05K 2201/10734

(57) ABSTRACT

The disclosed circuit board includes: a substrate portion that includes a first insulation layer and a first wiring layer buried by the first insulation layer, and a first element mounting portion and a second element mounting portion disposed on an upper surface of the substrate portion; a first protective layer disposed on the substrate portion; and an auxiliary layer that is disposed to overlap at least a part of a boundary area including a region between the first element mounting portion and the second element mounting portion, and has higher strength than the first protective layer.

### CROSS-REFERENCE TO RELATED APPLICATION

The present application claims the benefit of priority to Korean Patent Application No. 10-2023-0026119 filed on Feb. 27, 2023 in the Korean Intellectual Property Office, the entire contents of which are incorporated herein by reference.

### TECHNICAL FIELD

The present disclosure relates to a circuit board and a manufacturing method of the circuit board.

### BACKGROUND

Due to the rapid development of the IT industry and various service demands, semiconductors are being developed to be smaller and lighter than conventional semiconductors in terms of size and weight. In addition, in order to realize large-capacity fast information processing and multimedia performance, there is a growing demand for packaging in which several chips are mounted in one package.

When several chips are mounted in one package, differences in physical properties such as stiffness and thermal expansion characteristics may occur. This may cause an increased risk of warpage. Such a warpage may also occur in the case of using an interposer.

### SUMMARY

One aspect of the embodiments is to provide a circuit board that can improve the risk of warpage that may occur in a manufacturing process of a package circuit or a finished package substrate, and a manufacturing method of the circuit board.

However, the problem to be solved by the embodiments may be variously extended in the range of technical ideas included in the embodiments without being limited to the above-described problems.

A circuit board according to an embodiment includes: a substrate portion that includes a first insulation layer and a first wiring layer buried by the first insulation layer, and a first element mounting portion and a second element mounting portion disposed on an upper surface of the substrate portion; a first protective layer disposed on the substrate portion; and an auxiliary layer that is disposed to overlap at least a part of a first boundary area including a region between the first element mounting portion and the second element mounting portion, and has higher strength than the first protective layer.

The first boundary area may extend to an edge of the substrate portion.

An element mounting area including the first element mounting portion and the second element mounting portion, a dummy area disposed except for the element mounting area, and a warpage inflection area including a region where the first boundary area and the dummy area overlap may be disposed on the upper surface of the substrate portion, and the auxiliary layer may be disposed to overlap at least a part of the warpage inflection area.

At least one or more holes may be disposed inside the auxiliary layer.

The substrate portion further includes a third element mounting portion disposed on the upper surface of the substrate portion and a second boundary area including a region between the first element mounting portion and the third element mounting portion, and the warpage inflection area may further include a region in which the first boundary area and the second boundary area overlap.

The circuit board may further include: a pad layer that is disposed below the substrate portion; a second protective layer that is disposed below the substrate portion and includes an opening partially exposing the pad layer; and an external connection terminal connected to the pad layer through the opening of the second protective layer.

The circuit board may further include: a first link pad that is disposed on the substrate portion and connected with the first element mounting portion; and a second link pad that is disposed on the substrate portion and connected with the second element mounting portion, wherein the auxiliary layer may be disposed between the first link pad and the second link pad.

The first link pad, the second link pad, and the auxiliary layer may be disposed on the upper surface of the substrate.

The first link pad, the second link pad, and the auxiliary layer may be disposed on the same layer.

The auxiliary layer may have a thickness smaller than a thickness of the first or second link pad.

The first link pad, the second link pad, and the auxiliary layer may be embedded in the first protective layer and protrude from an upper surface of the first protective layer.

The auxiliary layer may be completely embedded in the first protective layer.

The circuit board may further include: an electronic element that is disposed on each of the first element mounting portion and the second element mounting portion; and an interposer substrate portion that is disposed on the substrate portion and the electronic element, wherein the interposer substrate portion may include an interposer insulation layer that includes a first side facing the substrate portion and a second side opposite to the first side, a first pad layer that is disposed on the first side of the interposer insulation layer; and a first auxiliary layer that is disposed on the first pad layer.

The interposer substrate portion may further include a third protective layer that is disposed to cover the first auxiliary layer under the first pad layer.

The first auxiliary layer may be disposed to overlap with the first boundary area at least partially.

The first auxiliary layer may be disposed to face the auxiliary layer.

A manufacturing method of a circuit board according to an embodiment includes: stacking a mask layer on a substrate portion that includes an insulation layer and a wiring layer buried in the insulation layer; exposing the substrate portion by partially etching the mask layer; forming an auxiliary layer and a link pad together on the exposed substrate portion; and removing the mask layer.

The manufacturing method of the circuit board may further include forming a protective layer on the substrate portion to bury the auxiliary layer.

According to the embodiment, it is possible to provide a circuit board for improving the risk of warpage on a substrate on which a plurality of electron elements are mounted by adding a simple process of forming a wire, and a manufacturing method of the circuit board.

However, it is clear that the effects of the embodiments are not limited to the above-described effects, and can be variously extended within a range that does not deviate from the spirit and region of the present disclosure.

### BRIEF DESCRIPTION OF THE DRAWINGS

FIG. 1 is a cross-sectional view of a circuit board according to an embodiment.

FIG. 2 is a top plan view that shows an element mounting portion is disposed in one row on the substrate portion.

FIG. 3 is a top plan view that shows the element mounting portion disposed in two rows on the substrate portion.

FIGS. 4A, 4B, and 4C each are a top plan view that shows the shape of the auxiliary layer.

FIG. 5 is a cross-sectional view of a circuit board according to another embodiment.

FIG. 6 to FIG. 16 are cross-sectional views of a manufacturing method of a circuit board according to an embodiment.

FIG. 17 is a cross-sectional view of a circuit board according to another embodiment.

### DETAILED DESCRIPTION OF THE EMBODIMENTS

Hereinafter, with reference to accompanying drawings, an embodiment of the present disclosure will be described in detail such that a person of an ordinary skill can easily practice it in the technical field to which the present disclosure belongs. The present disclosure may be embodied in many different forms and is not limited to the embodiments described herein.

The drawings and description are to be regarded as illustrative in nature and not restrictive. Like reference numerals designate like elements throughout the specification.

In addition, since the size and thickness of each component shown in the drawing is arbitrarily shown for better understanding and ease of description, the present disclosure is not necessarily limited to what is shown. In order to clearly express various layers and regions in the drawing, the size and thickness are enlarged. In addition, in the drawing, the thickness of some layers and regions is exaggerated for better understanding and ease of description.

The accompanying drawings are only for easy understanding of the embodiments disclosed in this specification, and the technical ideas disclosed in this specification are not limited by the accompanying drawings, and it should be understood to include all changes and equivalents or substitutes included in the spirit and technical range of the present disclosure.

Terms containing ordinal numbers, such as first, second, and the like can be used to describe various configurations elements, but the constituent elements are not limited by the terms. The terms are used only for the purpose of distinguishing one constituent element from another.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

Throughout the specification, terms such as “comprises” or “has” are intended to designate that there is a feature, number, step, operation, constituent element, part, or combination of these described in the specification, and it should be understood that the possibility of existence or addition of one or more other characteristics, numbers, steps, operations, constituent elements, parts, or combinations thereof is not precluded. Therefore, when it is expressed that a certain constituent element is “included”, it means that it may further include other constituent elements, not excluding other constituent elements, unless otherwise specified.

Further, throughout the specification, the phrase “on a plane” means viewing a target portion from the top, and the phrase “on a cross-section” means viewing a cross-section formed by vertically cutting a target portion from the side.

Throughout the specification, “connected” does not mean only when two or more constituent elements are directly connected, but also when two or more constituent elements are indirectly connected through another constituent element, or when physically connected or electrically connected, and it may include a case in which substantially integral parts are connected to each other although they are referred to by different names according to positions or functions.

Throughout the specification, a substrate has a structure that is broad in plane and thin in cross-section, the “planar direction of the substrate” means a direction parallel to a wide and flat surface of the substrate, and the “thickness direction of the substrate” means a direction perpendicular to the wide and flat surface of the substrate. It can mean a vertical direction.

Various embodiments and exemplary variations are described in detail by referring to the drawings.

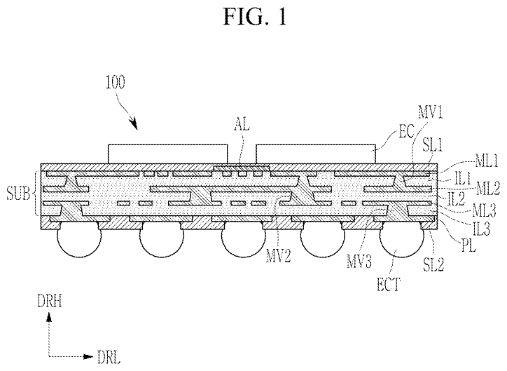

FIG. 1 is a cross-sectional view of a circuit board according to an embodiment. A height direction DRH means a direction that is perpendicular to a surface of a first insulation layer IL1. A length direction DRL means a direction parallel to the surface of the first insulation layer IL1, and may be a direction that intersects (or is orthogonal to) the height direction DRH. In addition, a width direction DRW is a direction parallel to the surface of the first insulation layer IL1, and may be a direction that simultaneously intersects (or is orthogonal to) the height direction DRH and the length direction DRL.

Referring to FIG. 1, a circuit board 100 according to the present embodiment may include a substrate portion SUB, a pad layer PL disposed under the substrate portion SUB, an auxiliary layer AL on the substrate portion SUB, a protective layer PL, and an external connection terminal ECT.

The substrate portion SUB may include an insulation layer IL, a via layer MV, and a wiring layer ML.

The insulation layer IL may include a first insulation layer IL1, a second insulation layer IL2 disposed under the first insulation layer IL1, and a third insulation layer IL3 disposed under the second insulation layer IL2. The insulation layer IL may include a thermosetting resin such as epoxy resin, polyimide, or the like, or a thermoplastic resin such as polyethylene (PE), polycarbonate (PC), or polyvinyl chloride (PVC). For example, the insulation layer IL may include an Ajinomoto Build-up Film (ABF) and the like. The Ajinomoto build-up film (ABF) may be a polymeric epoxy film available from Ajinomoto Fine-Techno Company, Inc. In addition, the insulation layer IL may include a silica filler.

The wiring layer ML may include a first wiring layer ML1 buried by the first insulation layer IL1, a second wiring layer ML2 buried by the second insulation layer IL2, and a third wiring layer ML3 buried by the third insulation layer IL3. The wiring layer ML may transmit electrical signals. The wiring layer ML may include a conductive material such as copper (Cu), aluminum (Al), silver (Ag), tin (Sn), gold (Au), nickel (Ni), lead (Pb), titanium (Ti), or their alloys.

The via layer MV may include a first via layer MV1 disposed in the first insulation layer IL1, a second via layer MV2 disposed in the second insulation layer IL2, and a third via layer MV3 disposed in the third insulation layer IL3. The via layer MV may include conductive material such as copper (Cu), aluminum (AI), silver (Ag), tin (Sn), gold (Au), nickel (Ni), lead (Pb), titanium (Ti), or their alloys.

In the present embodiment, the substrate portion SUB is exemplified as including three layers of the insulation layer IL, the wiring layer ML, and the via layer MV, respectively, but is not limited thereto, and but it is also possible to include more or fewer insulation layers IL, wiring layers ML, and via layers MV, which also belongs to the range of the present disclosure.

The pad layer PL may be disposed under the substrate portion SUB. The pad layer PL may function as a pad to which the external connection terminal ECT is attached.

A plurality of electronic elements EC may be mounted on the substrate portion SUB. For example, the position where the plurality of electronic elements EC are mounted may be formed by etching the protective layer SL.

An auxiliary layer AL may be disposed on the substrate portion SUB. Here, the auxiliary layer AL may include a metallic material such as copper (Cu), aluminum (Al), silver (Ag), tin (Sn), gold (Au), nickel (Ni), lead (Pb), titanium (Ti), or their alloys, but is not limited thereto.

A protective layer SL may include a first protective layer SL1 disposed over the substrate portion SUB and a second protective layer SL2 disposed under the substrate portion SUB. The first protective layer SL1 may be formed to bury the auxiliary layer AL. The second protective layer SL2 may be formed to have an opening exposing a portion of the pad layer PL. For example, the protective layer SL may be formed of a solder resist.

The external connection terminal ECT may be connected to the pad layer PL through an opening of the second protective layer PL2. The external connection terminal ECT may electrically connect between an electronic element EC and an external device. For example, the external connection terminal ECT may be a solder ball.

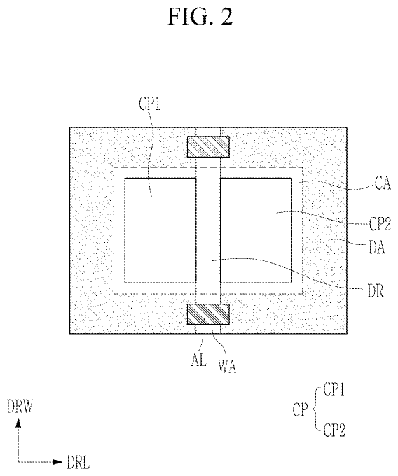

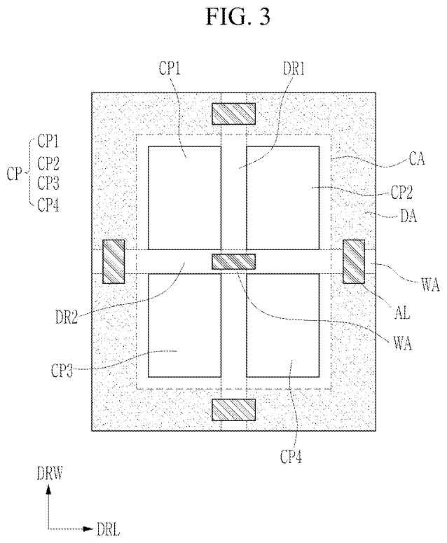

Hereinafter, referring to FIG. 2 and FIG. 3 together with FIG. 1, the auxiliary layer according to the embodiment will be described. FIG. 2 is a top plan view that shows an element mounting portion is disposed in one row on the substrate portion SUB, and FIG. 3 is a top plan view that shows the element mounting portion disposed in two rows on the substrate portion SUB.

Referring to FIG. 2 and FIG. 3, an element mounting area CA, a dummy area DA, a boundary area DR, a warpage inflection region WA, and an auxiliary layer AL may be disposed on an upper surface of the substrate portion SUB.

The element mounting area CA may include a plurality of element mounting portions CP. The element mounting area CA may be a region formed along an outer vicinity of a plurality of element mounting portions CP. The electronic element EC may be mounted on the element mounting portion CP. The element mounting portion CP may be disposed on the first wiring layer ML1 of the substrate portion SUB. The element mounting portion CP may substantially match the size of the electron device EC on a plane. The element mounting portion CP may be disposed where an opening is formed in the first protective layer SL1.

The dummy area DA may be a region disposed on an edge of the upper surface of the substrate portion SUB. The dummy area DA may be disposed on the upper surface of the substrate portion SUB except for the element mounting area CA.

The boundary area DR may be disposed on the upper surface of the substrate portion SUB. The boundary area DR may be formed along a gap between positions where adjacent electronic elements EC mounted. The boundary area DR may include a region between the plurality of element mounting portions CP. For example, when the first element mounting portion CP1 and the second element mounting portion CP2 are disposed on the upper surface of the substrate portion SUB, the boundary area DR may be formed in a region between the first element mounting portion CP1 and the second element mounting portion CP2.

Three or more element mounting portions CP may be disposed on the upper surface of the substrate portion SUB. Between three or more element mounting portions CP, two or more boundary areas DR including regions between the element mounting portions CP may be positioned. For example, the boundary area DR includes a first boundary area DR1 including a region between the first element mounting portion CP1 and the second element mounting portion CP2, and a second boundary area DR2 including a region between the first element mounting portion CP1 and the third element mounting portion CP3. Even when the plurality of element mounting portions CP are formed on the upper surface of the substrate portion SUB, the boundary area DR may include a region between adjacent element mounting portions CP. The boundary area DR may include a region extending from a region between the element mounting portion CP to an edge of the substrate portion SUB.

The warpage inflection region WA may include a region where the dummy area DA and the boundary area DR overlap. In addition, the warpage inflection region WA may include a portion where two or more boundary areas DR overlap. For example, the warpage inflection area WA may include a region in which the first boundary area DR1 and the second boundary area DR2 overlap. The warpage inflection area WA may be a region where a warpage behavior due to differences in physical properties that may easily occur along the electronic elements EC.

The auxiliary layer AL may be disposed such that at least a part of it overlaps with the boundary area DR on the upper surface of the substrate portion SUB. The auxiliary layer AL may be formed in the form of a rectangular shape panel. The auxiliary layer AL may be disposed orthogonal to a length direction of the boundary area DR. That is, the auxiliary layer AL may be disposed to pass through the boundary area DR in the width direction. Since the warpage behavior is highly likely to occur along the length direction of the boundary area DR, when the auxiliary layer AL is disposed to penetrate a width direction of the boundary area DR, the warpage behavior can be more effectively controlled.

The auxiliary layer AL may be disposed such that at least a part overlaps with the warpage inflection area WA. The auxiliary layer AL may be disposed to a position and a direction that can control the warpage behavior that can increase along between electronic elements EC. For example, the auxiliary layer AL may be disposed through the warpage inflection area WA so as to be orthogonal to the length direction of the boundary area DR.

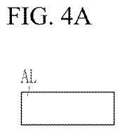

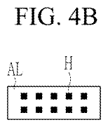

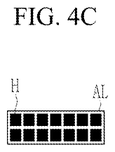

FIGS. 4A, 4B, and 4C each are a top plan view that shows the shape of the auxiliary layer.

Referring to FIG. 4, the auxiliary layer AL may be formed in the form of a panel. The auxiliary layer AL is disposed such that at least a part overlaps with the warpage inflection area WA, thereby preventing a warpage phenomenon caused by differences in physical properties including stiffness or thermal expansion characteristics between substrates or electronic elements that may occur along the boundary area DR from occurring.

The auxiliary layer AL may be formed of a material that can compensate for the difference in physical properties. The auxiliary layer AL may be formed of a material having higher strength than the protective layer SL. For example, the auxiliary layer AL may be formed of a component including a metal such as copper (Cu), aluminum (AI), silver (Ag), tin (Sn), gold (Au), nickel (Ni), lead (Pb), titanium (Ti), or alloys thereof.

The size or thickness of the auxiliary layer AL may be adjusted to compensate for the difference in physical properties. In addition, the auxiliary layer AL may be formed in various shapes. In the embodiment, the auxiliary layer AL is shown in the form of a pad of a rectangular shape, but is not limited thereto and may have various shapes.

A hole H may be formed in the auxiliary layer AL. For example, the size, quantity, or position of holes H formed in the auxiliary layer AL may be changed according to the physical properties or relative positions of the electronic element EC mounted on the circuit board 100 and the protective layer SL. Warpage due to the difference in physical properties can be finely adjusted by adjusting the size, quantity, or position of holes H formed in the auxiliary layer AL. Although a quadrangular hole is shown in the embodiment, it is not limited thereto, and holes of various shapes including a circular shape may be formed, and this also belongs to the scope of the present disclosure.

In the circuit board according to the present embodiment, in the case of forming a package substrate on which a plurality of electronic elements EC are mounted as a circuit board, particularly a coreless substrate on which a plurality of electronic elements EC are mounted, warpage in the form of severe bending may occur along a dividing line between electronic elements EC. Thus, the risk of warpage that may occur in the manufacturing process of the package circuit or in the finished package substrate may be improved by forming the auxiliary layer AL.

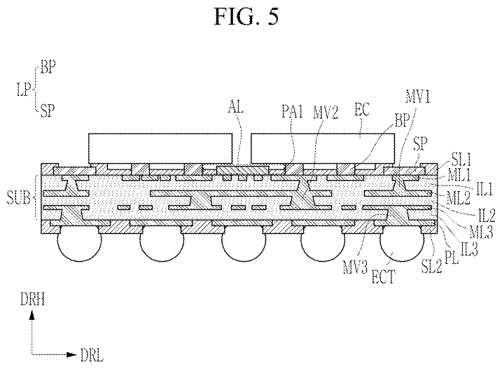

Hereinafter, referring to FIG. 5, a circuit board according to another embodiment will be described. FIG. 5 is a cross-sectional view of a circuit board according to another embodiment.

Referring to FIG. 5, a circuit board according to another embodiment is similar to the circuit board according to the embodiment described with reference to FIG. 1 to FIG. 4. A detailed description of the same constituent elements is omitted.

Referring to FIG. 5, a circuit board according to another embodiment may further include a link pad LP disposed on a first wiring layer ML1. The link pad LP may include a bump pad BP and/or a solder pad SP. The link pad LP may be disposed within an element mounting portion CP. The electronic element EC may be mounted on the link pad LP. For example, formation of the link pad LP may use the same process as formation of a wiring layer ML.

A boundary area DR may include a region between link pads LP (BP and SP). The link pad LP may be disposed within the element mounting portion CP. The boundary area DR may include a region between link pads LP each disposed within adjacent element mounting portions CP. For example, the boundary area DR may include a region between bump pads BP located at positions closest to each other in two adjacent element mounting portions CP. That is, the boundary area DR may include a region between a bump pad BP disposed close to an adjacent element mounting portion CP among bump pads BP disposed in one element mounting portion CP and a bump pad BP disposed close to the one element mounting portion CP among the bump pads BP disposed in the adjacent element mounting portion CP. The boundary area DR may include a region between adjacent solder pad SPs and a region between a solder pad SP and an adjacent bump pad BP, and this is also the same as the case of including the region between bump pads BP described above. The boundary area DR may extend to an edge of a substrate portion SUB.

An auxiliary layer AL may be disposed such that at least a part overlaps with the boundary area DR. The auxiliary layer AL may be disposed inside the boundary area DR. That is, the auxiliary layer AL may be disposed between the link pads LPs so as to not contact the link pads LP. The auxiliary layer AL may be disposed such that a length direction intersects a length direction of the boundary area DR. For example, the length direction of the auxiliary layer AL may be disposed to be orthogonal to a length direction of the boundary area DR. The auxiliary layer AL may be disposed to partially overlap the element mounting portion CP. For example, the auxiliary layer AL may be disposed between a first link pad connected to a first element mounting portion CP1 disposed on the substrate portion SUB and a second link pad connected to a second element mounting portion CP2. Therefore, the first link pad, the second link pad, and the auxiliary layer AL may be disposed on an upper surface of the substrate portion SUB. That is, the first link pad, the second link pad, and auxiliary layer AL may be disposed on the same layer.

Even on the substrate on which the link pad LP is formed, there is a risk of warpage due to the difference in physical properties between electronic elements EC. Such a warpage behavior can be controlled without an additional process by forming the auxiliary layer AL on the same plane as the link pad LP.

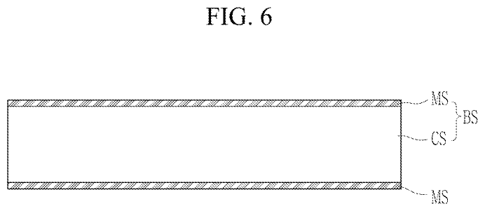

Hereinafter, referring to FIG. 6 to FIG. 16, a manufacturing method of a circuit board according to an embodiment will be described. FIG. 6 to FIG. 16 are cross-sectional views of a manufacturing method of a circuit board according to an embodiment.

Referring to FIG. 6, a carrier substrate BS may be prepared to form the substrate portion SUB. The carrier substrate BS may include a core portion CS and thin film metal layers MS stacked on both sides of the core portion CS. The substrate portion SUB may be formed on both sides of the carrier substrate BS, but one side will be described below.

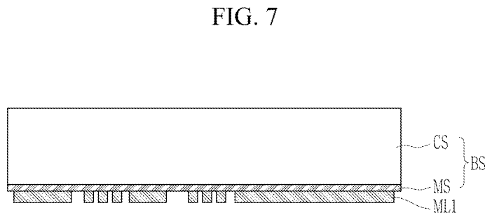

Referring to FIG. 7, a first wiring layer ML1 may be formed on the carrier substrate BS.

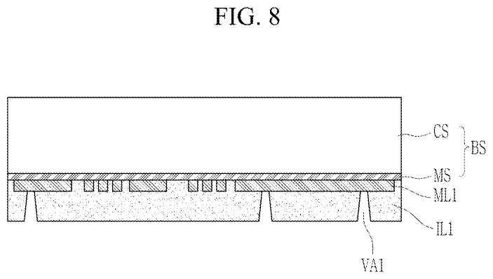

Referring to FIG. 8, a first insulation layer IL1 may be stacked on the first wiring layer ML1 such that the first wiring layer ML1 may be buried with the first insulation layer IL1, and a first via VA1 may be formed in the first insulation layer IL1.

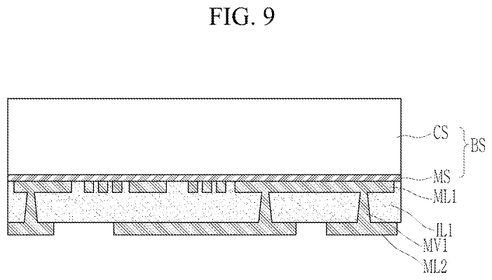

Referring to FIG. 9, a first via layer MV1 may be formed in the first via VA1 of the first insulation layer IL1, and a second wiring layer ML2 may be formed on the first insulation layer IL1.

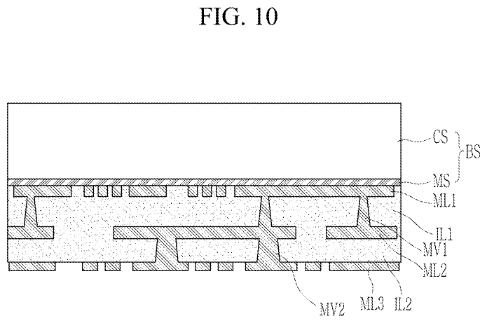

Referring to FIG. 10, a second insulation layer IL2 may be stacked such that the second wiring layer ML2 may be buried with the second insulation layer IL2. A second via may be formed in the second insulation layer IL2, and a second via layer ML2 may be formed in the second via. A third wiring layer ML3 may be formed on the second insulation layer IL2.

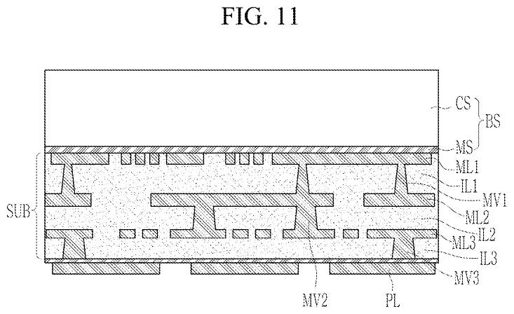

Referring to FIG. 11, a third insulation layer IL3 may be stacked such that the third wiring layer ML3 may be buried with the third insulation layer IL3, and a third via may be formed in the third insulation layer IL3. The third via layer ML3 may be formed in the third via, and a pad layer PL may be formed on the third insulation layer IL3.

The insulation layers IL (IL1, IL2, and IL3), the wiring layers ML (ML1, ML2, and ML3), and the via layers MV (MV1, MV2, and MV3) formed as described above may form the substrate portion SUB. In the present embodiment, the substrate portion SUB is illustrated as including three layers of an insulation layer IL, a wiring layer ML, and a via layer MV, respectively, but it is also possible to include one or two layers or more layers of the insulation layer IL, the wiring layer ML, and the via layer MV, which also belongs to the range of the present disclosure.

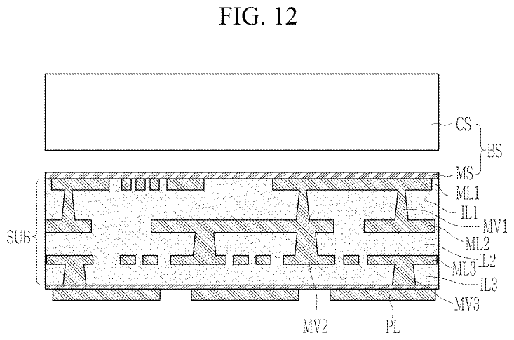

Referring to FIG. 12, the core portion CS may be peeled from the substrate portion SUB. In this case, the thin film metal layer MS of the carrier substrate BS may be disposed on the substrate portion SUB without peeling off.

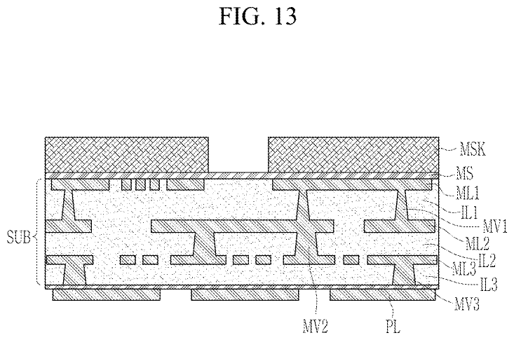

Referring to FIG. 13, a mask layer MSK may be stacked on the thin film metal layer MS, and the mask layer MSK may be partially removed. The substrate portion SUB may be exposed at a position where the mask layer MSK is partially removed. The mask layer MSK may be formed of a dry film resist (DFR). A position where the substrate portion SUB is exposed by removing the mask layer MSK may include a position overlapping the boundary area DR.

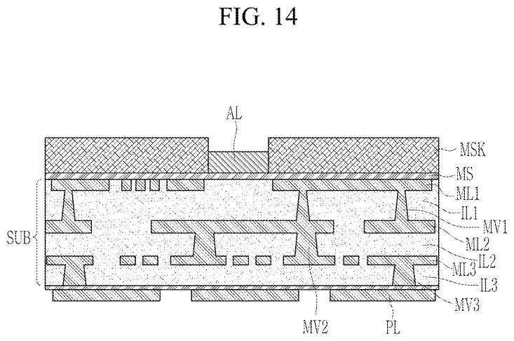

Referring to FIG. 14, the auxiliary layer AL may be formed at a position where the mask layer MSK is partially removed. The auxiliary layer AL may be formed together with the link pad LP. For example, the auxiliary layer AL and the link pad LP may be formed together using a process of forming the wiring layer ML. In this case, the auxiliary layer AL and the link pad LP may be formed of the same layer. The auxiliary layer AL and the link pad LP may be formed of the same material.

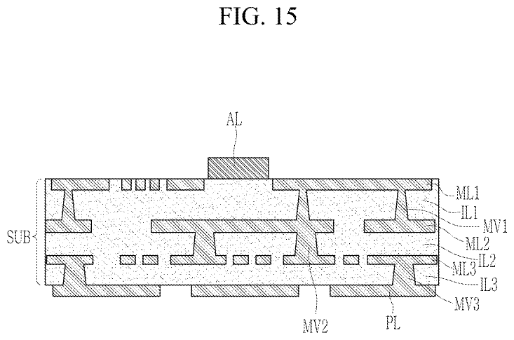

Referring to FIG. 15, a residual mask layer MSK may be removed and the thin film metal layer MS may be etched.

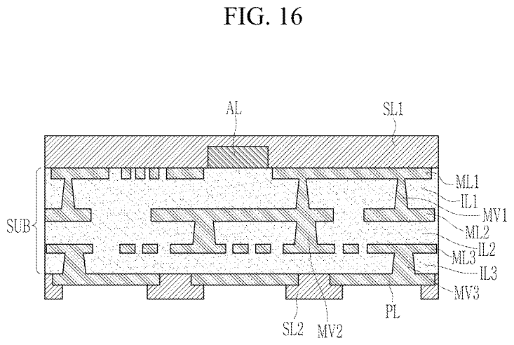

Referring to FIG. 16, a first protective layer SL1 may be formed on the first insulation layer IL1, and a second protective layer SL2 may be formed under the substrate portion SUB. The first protective layer SL1 may bury the auxiliary layer AL. The second protective layer SL2 may expose a part of the pad layer PL.

According to the manufacturing method of the circuit board according to the present embodiment, the auxiliary layer AL is formed using the process of forming the wiring layer ML, and the rigidity of the substrate is added by adding a simple process of insulation by covering the formed auxiliary layer AL with the protective layer SL, while securing the same function.

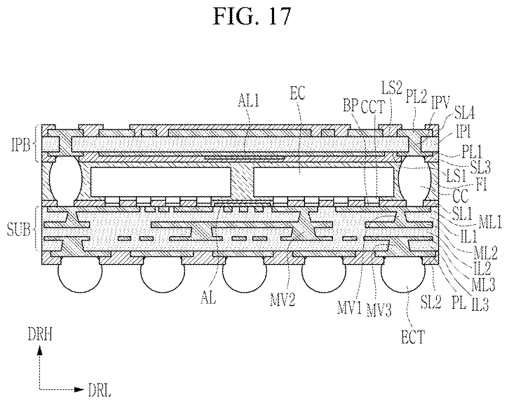

Hereinafter, referring to FIG. 17, a circuit board according to another embodiment will be described. FIG. 17 is a cross-sectional view of a circuit board according to another embodiment.

Another embodiment shown in FIG. 17 is substantially equivalent to the embodiment shown in FIG. 1 and FIG. 16 except that an interposer substrate part is added, and thus repeated descriptions are omitted.

Referring to FIG. 17, a circuit board according to another embodiment may further include an interposer substrate portion IPB, a filling layer FI, and a first auxiliary layer AL1.

An electronic element EC may be mounted on an element mounting portion CP on a substrate portion SUB. The electronic element EC may be disposed between the substrate portion SUB and the interposer substrate portion IPB in a height direction DRH. The electronic element EC may be connected to the substrate portion SUB through an element connection terminal CCT. A bump pad BP linked to the element connection terminal CCT may be disposed on the substrate portion SUB.

The interposer substrate portion IPB may be disposed on the substrate portion SUB and an electronic element EC. The interposer substrate portion IPB may include an interposer insulation layer IPI, a third protective layer SL3, a fourth protective layer SL4, an interposer wiring layer IML, and a first auxiliary layer AL1.

The interposer insulation layer IPI may include at least one material selected from phenol resin, epoxy resin, and polyimide. For example, the interposer insulation layer IPI may include a material selected from polyimide, flame retardant 4 (FR-4), tetrafunctional epoxy, polyphenylene ether, epoxy/polyphenylene oxide), bismaleimide triazine (BT), cyanate ester, and liquid crystal polymer. The interposer insulation layer IPI may include a first surface LS1 facing the substrate portion SUB and a second surface LS2 facing the first surface LS1.

The interposer wiring layer IML may include a first pad layer PL1 on the first surface LS1 of the interposer insulation layer IPI, a second pad layer PL2 on the second surface LS2 of the interposer insulation layer IPI, and an interposer via layer IPV disposed on the interposer insulation layer IPI. A first conductive connector CC may be connected to the first pad layer PL1. A connector such as a solder ball may be attached to the second pad layer PL2. The interposer via layer IPV may connect the first pad layer PL1 and the second pad layer PL2. The interposer via layer IPV may penetrate the interposer insulation layer IPI.

The interposer wiring layer IML may be, for example, a metal such as copper (Cu), aluminum (AI), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but is not limited thereto.

The third protective layer SL3 may be disposed on the first surface LS1 of the interposer insulation layer IPI and may expose a portion of the first pad layer PL1. The fourth protective layer SL4 may be disposed on the second surface LS2 of the interposer insulation layer IPI, and may expose a portion of the second pad layer PL2.

The conductive connector CC may be disposed between the interposer substrate portion IPB and the substrate portion SUB. The conductive connector CC may connect the substrate portion SUB and the interposer substrate portion IPB. The conductive connector CC may have an extended column shape connected to the first pad layer PL1 of the interposer substrate portion IPB and the first wiring layer ML1 of the substrate portion SUB.

The filling layer FI may be disposed on the substrate portion SUB. The filling layer FI may serve to protect the substrate portion SUB, the electronic element EC, the conductive connector CC, and the interposer substrate portion IPB from an external environment. The filling layer FI may be formed to cover at least a portion of each of the substrate portion SUB, the electronic element EC, the conductive connector CC, and the interposer substrate portion IPB. For example, the filling layer FI may cover an upper surface of the substrate portion SUB, side and upper surfaces of the electronic element EC, a side surface of the conductive connector CC, and a bottom surface of the interposer substrate portion IPB. In addition, the filling layer FI may be formed to fill a gap between the bottom surface of the interposer substrate portion IPB and the electronic element EC.

The filling layer FI may include an insulating filler. For example, the filling layer FI may include an epoxy-based molding resin or a polyimide-based molding resin, but is not limited thereto.

The first auxiliary layer AL1 may be disposed under the first pad layer PL1. The first auxiliary layer AL1 may be disposed such that at least a part overlaps with a region between a plurality of electronic elements EC on the first pad layer PL1. That is, the first auxiliary layer AL1 may be disposed to overlap at least partially with the boundary area DR of the substrate portion SUB on a plane. For example, the first auxiliary layer AL1 may be disposed to correspond to the auxiliary layer AL disposed on the substrate portion SUB. That is, the auxiliary layer AL1 may be disposed to overlap on a plane with the auxiliary layer AL disposed on the substrate portion SUB.

In a process of mounting the interposer substrate portion IPB, the risk of non-wet defects is high and thus it can be vulnerable to warpage behavior. However, such vulnerability may be further reinforced by forming the auxiliary layer AL on the substrate portion SUB and the first auxiliary layer AL1 on the interposer substrate portion IPB together. In order to control warpage behavior, properties, thickness, or size of the first auxiliary layer AL1 may be adjusted. In addition, the warpage behavior can be finely controlled by forming the holes H described in the auxiliary layer AL in the first auxiliary layer AL1 and adjusting the number or size of the holes H.

While this invention has been described in connection with what is presently considered to be practical embodiments, it is to be understood that 15 the invention is not limited to the disclosed embodiments. On the contrary, it is intended to cover various modifications and equivalent arrangements included within the spirit and scope of the appended claims.

### DESCRIPTION OF SYMBOLS

AL: auxiliary layer
AL1: first auxiliary layer
BP: bump pad
BS: carrier substrate
CC: conductive connector
CCT: element connection terminal
CP: element mounting portion
ECT: external connection terminal
DA: dummy portion
DR: boundary area
EC: electronic element
FI: filling layer
IPB: interposer substrate portion
IL: insulation layer
IPI: interposer insulation layer
LP: link pad
ML: wiring layer
MV: via layer
PL: pad layer
SP: solder pad
SUB: substrate portion
SL: protective layer

What is claimed is:

1. A circuit board comprising:
a substrate portion that includes a first insulation layer and a first wiring layer buried by the first insulation layer, and a first element mounting portion and a second element mounting portion disposed on an upper surface of the substrate portion;
a first protective layer disposed on the substrate portion; and
an auxiliary layer that is disposed to overlap at least a part of a first boundary area including a region between the first element mounting portion and the second element mounting portion, the auxiliary layer having higher strength than the first protective layer.

2. The circuit board of claim 1, wherein
the first boundary area extends to an edge of the substrate portion.

3. The circuit board of claim 2, wherein:
an element mounting area including the first element mounting portion and the second element mounting portion,
a dummy area disposed except for the element mounting area, and
a warpage inflection area including a region where the first boundary area and the dummy area overlap are disposed on the upper surface of the substrate portion, and
the auxiliary layer is disposed to overlap at least a part of the warpage inflection area.

4. The circuit board of claim 1, wherein
at least one or more holes are disposed inside the auxiliary layer.

5. The circuit board of claim 3, wherein
the substrate portion further includes a third element mounting portion disposed on the upper surface of the substrate portion and a second boundary area including a region between the first element mounting portion and the third element mounting portion, and
the warpage inflection area further includes a region in which the first boundary area and the second boundary area overlap.

6. The circuit board of claim 1, further comprising:
a pad layer that is disposed below the substrate portion;
a second protective layer that is disposed below the substrate portion and includes an opening partially exposing the pad layer; and
an external connection terminal connected to the pad layer through the opening of the second protective layer.

7. The circuit board of claim 1, further comprising:
a first link pad that is disposed on the substrate portion and connected with the first element mounting portion; and
a second link pad that is disposed on the substrate portion and connected with the second element mounting portion,
wherein the auxiliary layer is disposed between the first link pad and the second link pad.

8. The circuit board of claim 7, wherein
the first link pad, the second link pad, and the auxiliary layer are disposed on the upper surface of the substrate.

9. The circuit board of claim 8, wherein
the first link pad, the second link pad, and the auxiliary layer are disposed on the same layer.

10. The circuit board of claim 8, wherein
the auxiliary layer has a thickness smaller than a thickness of the first or second link pad.

11. The circuit board of claim 8, wherein
the first link pad, the second link pad, and the auxiliary layer are embedded in the first protective layer and protrude from an upper surface of the first protective layer.

12. The circuit board of claim 1, wherein
the auxiliary layer is completely embedded in the first protective layer.

13. The circuit board of claim 1, further comprising:
an electronic element that is disposed on each of the first element mounting portion and the second element mounting portion; and
an interposer substrate portion that is disposed on the substrate portion and the electronic element,
wherein the interposer substrate portion comprises:
an interposer insulation layer that includes a first side facing the substrate portion and a second side opposite to the first side;
a first pad layer that is disposed on the first side of the interposer insulation layer; and
a first auxiliary layer that is disposed on the first pad layer.

14. The circuit board of claim 13, wherein
the interposer substrate portion further comprises a third protective layer that is disposed to cover the first auxiliary layer under the first pad layer.

15. The circuit board of claim 13, wherein
the first auxiliary layer is disposed to overlap with the first boundary area at least partially.

16. The circuit board of claim 15, wherein
the first auxiliary layer is disposed to face the auxiliary layer.

17. A manufacturing method of a circuit board, comprising:
stacking a mask layer on a substrate portion that includes an insulation layer and a wiring layer buried in the insulation layer,
exposing the substrate portion by partially etching the mask layer,
forming an auxiliary layer and a link pad together on the exposed substrate portion; and
removing the mask layer.

18. The manufacturing method of the circuit board of claim 17, further comprising forming a protective layer on the substrate portion to bury the auxiliary layer.
